(19) United States
(12) Patent Application Publication
(10) Pub. No.: US 2006/0122067 A1
(43) Pub. Date: Jun. 8, 2006

(54) Fault current limiting system

(76) Inventor: Matthew J. Holcomb, Metamora, MI (US)

Correspondence Address: Stephen M. De Klerk;BLAKELY, SOKOLOFF, TAYLOR & ZAFMAN LLP, Seventh Floor, 12400 Wilshire Boulevard, Los Angeles, CA, 90025, US

(21) Appl. No.: 11/259,988

(22) Filed: Oct. 26, 2005

Related U.S. Application Data
(60) Provisional application No. 60/622,476, filed on Oct. 26, 2004.
(60) Provisional application No. 60/629,079, filed on Nov. 18, 2004.
(60) Provisional application No. 60/637,176, filed on Dec. 17, 2004.
(60) Provisional application No. 60/703,660, filed on Jul. 29, 2005.

(51) Int. Cl. H01L 39/24

(52) U.S. Cl. 505/124

(57) ABSTRACT

A fault current limiting system is described. A fault current limiting component is made of a superconductor metal matrix material having an n-value of at least 15 at 15K.

### CROSS-REFERENCE TO RELATED APPLICATIONS

This application claims priority from U.S. Provisional Patent Application No. 60/622,476 filed on Oct. 26, 2004; U.S. Provisional Patent Application No. 60/629,079, filed on Nov. 18, 2004; U.S. Provisional Patent Application No. 60/637,176, filed on Dec. 17, 2004; and U.S. Provisional Patent Application No. 60/703,660, filed on Jul. 29, 2005, all of which are incorporated herein by reference in their entirety.

### BACKGROUND OF THE INVENTION

1). Field of the Invention

The present invention relates to a superconducting composite fault current limiting system.

2). Discussion of Related Art

A fault current limiter (FCL) system reduces the amplitude of a high-current surge (i.e., a fault current) in a utility grid which may occur as a result of lightning strikes, downed tree limbs, crossed transmission lines, etc. Superconducting materials, in principle, are ideal FCLs because the resistance of the material is zero at temperatures below the critical temperature (T_{C}), in magnetic fields less than the critical magnetic field, and when carrying an electrical current less than the critical current (I_{C}). In a current limiting application, the superconductor has zero resistance for currents less than I_{C}, and becomes highly resistive at currents above I_{C}. The rapid increase in the resistance of the material for currents in excess of the critical current of the superconductor adds impedance to the electrical grid, which effectively attenuates the fault current and thus protects expensive transmission and distribution equipment from damage.

### SUMMARY OF THE INVENTION

The invention provides a fault current limiting system which includes a refrigeration system, first and second leads, and an FCL component thermally connected to the refrigeration system so as to be maintained at a cryogenic temperature, and having opposing terminals connected to ends of the first and second leads, respectively.

The FCL component is preferably made of a superconductor material having an n-value of at least 15 at a temperature of at least 15K.

The FCL component can preferably carry a current of ate least 500A.

The FCL component is preferably made of a superconducting material which includes a plurality of superconductor particles and a metal in proximity to the superconductor particles, to be driven to a superconducting state by the superconducting particles to provide a superconducting path from the first lead to the second lead.

The FCL component may define a meandering superconducting path.

The FCL component preferably has a plurality of alternating slits formed therein to define a meandering superconducting path.

The slits may be formed in a manner so that a three-dimensional meandering path is defined.

The FCL component may have a plurality of plates, each plate having a plurality of alternating slits formed therein.

The FCL system may further include a shunt with impedance connected between the first and second leads in parallel with the FCL component.

The refrigeration system may include a cryogenic enclosure, the first and second leads extending into the cryogenic enclosure, a cryogenic fluid being located within the cryogenic enclosure, and a refrigeration module connected to the cryogenic enclosure to maintain the cryogenic fluid at a cryogenic temperature, the FCL component being located within the cryogenic fluid.

The FCL system may have first and second cryogenic fluids, the first cryogenic fluid being at a lower temperature than the second cryogenic fluid, the FCL component being located in the first cryogenic fluid, the first and second leads being hybrid leads, each including an HTS section and a metal section, a lower end of the HTS section being located in the first cryogenic fluid, and an upper end of the HTS section and a lower end of the metal section being located in the second cryogenic fluid.

The invention also provides an FCL component. The FCL component may be made of a superconductor material having an n-value of at least 15 at a temperature of at least 15K. The FCL component may include a plurality of superconductor particles and a metal in proximity to the superconductor particles, to be driven to a superconducting state by the superconductor particles to provide a superconducting path between opposing terminals thereof.

### BRIEF DESCRIPTION OF THE DRAWINGS

The invention is further described by way of example with reference to the accompanying drawings, wherein:

FIG. 1 is a graph of electric field vs. current, illustrating the meaning of an n-value;

FIG. 2 is an equivalent circuit diagram of an FCL module;

FIG. 3 is a graph of impedance vs. current for an FCL module;

FIG. 4 is a graph of n-value vs. % volume metal matrix material in superconducting metal matrix composites;

FIG. 5 is a graph of critical current vs. % volume metal matrix material in superconducting metal matrix composites;

FIG. 6 is a graph of normalized resistance vs. current for an FCL module, illustrating the difference in quench mechanisms between Type I and Type II superconductors;

FIG. 7 is a side view of an FCL module consisting of a magnetoresistive metal matrix material in the SMMC, according to one embodiment of the invention;

FIG. 8 is a diagram illustrating how stress fractures in an SMMC FCL component may be healed with the application of heat;

FIG. 9A is a circuit diagram illustrating the use of an FCL system to protect electrical components in an electrical distribution grid;

FIG. 9B is a side view of an FCL module of the FCL system of FIG. 9A;

FIG. 10 is a cross-sectional side view of an MgB₂/Ga SMMC FCL component assembly;

FIG. 11 is a side view of an FCL system in which the FCL module is within the low temperature region of the FCL system, according to a first embodiment of the invention;

FIG. 12 is a side view of an FCL system in which the resistive current limiting shunt is located outside of the low temperature region of the FCL system, according to a second embodiment of the invention;

FIG. 13 is a graph of electric field vs. current, illustrating the critical current requirements of the HTS and MgB₂-based components to protect the HTS components from damage during a fault;

FIG. 14 is a circuit diagram illustrating the use of an FCL system to protect electrical components in a 10 MW (10 kV, 1 kA) electrical distribution grid;

FIG. 15 is a side view illustrating a method in which multiple HTS ceramic components are assembled in series using resistive copper connection joints;

FIG. 16 is a side view illustrating a method in which MgB₂/Ga powder is formed into a thin square plate;

FIG. 17 is a side view of an MgB₂/Ga plate after a performing a series of alternating cuts to create a meandering current path;

FIGS. 18A and 18B are side and perspective views illustrating the method of assembling the bulk MgB₂/Ga meander current path FCL component by assembling a series of plates;

FIG. 19 is a perspective view of the assembled meander current path FCL component after fusing individual plates thereof into a solid body;

FIG. 20 is a cross-sectional side view of an FCL system in which the meander current path FCL component of FIG. 19 is within the low temperature region of the FCL system, according to a third embodiment of the invention; and

FIG. 21 is a cross-sectional side view of a hybrid FCL system using a meander path FCL component and a resistive current limiting shunt, according to a fourth embodiment of the invention.

### DETAILED DESCRIPTION OF THE INVENTION

FCL Functioning and Parameters

Current limiting systems possess electrical resistivities that are a function of the electrical current which passes through the system. Superconducting materials (e.g., wire, rods, tubes, etc.) are current limiting systems because the resistivity of a superconductor is a strong function of the current that passes through the material.

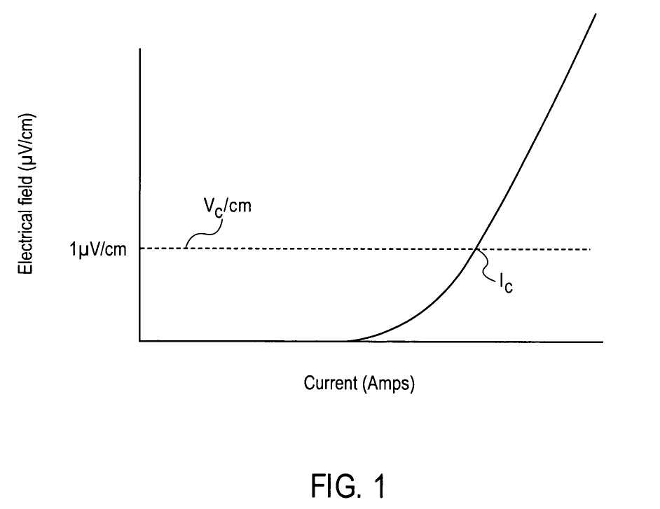

FIG. 1 shows a typical voltage per centimeter (V_{C}/cm) vs. current graph of a superconductor. A current-carrying superconducting material displays a zero voltage drop per centimeter for applied currents less than the critical current. Critical currents (I_{C}) are determined by assuming a value for a critical electric field (or voltage measured along the sample). A critical electric field of 1 μV/cm is typically used to determine the critical current of the High-Temperature Superconducting (HTS) ceramics and metallic boride superconducting materials.

For currents in excess of I_{C}, it is known that the electric field across the superconductor follows the well-known power law expression:
V=V_{C}(I/I_{C})ⁿ
For currents greater than I_{C}, the “n-value” describes the manner in which the voltage develops within the superconductor, or equivalently how the material transitions from a zero-resistance superconducting state to a resistive normal metallic state. For a given rate of increasing current passing through the superconducting material, a higher n-value suggests that the material will make the transition to the equivalent of a normal metallic state more quickly.

An effective current limiting system should switch rapidly from the zero-resistance superconducting state to the highly resistive normal state with increasing current. In other words, an effective current limiting system should possess a high n-value (i.e., n>5).

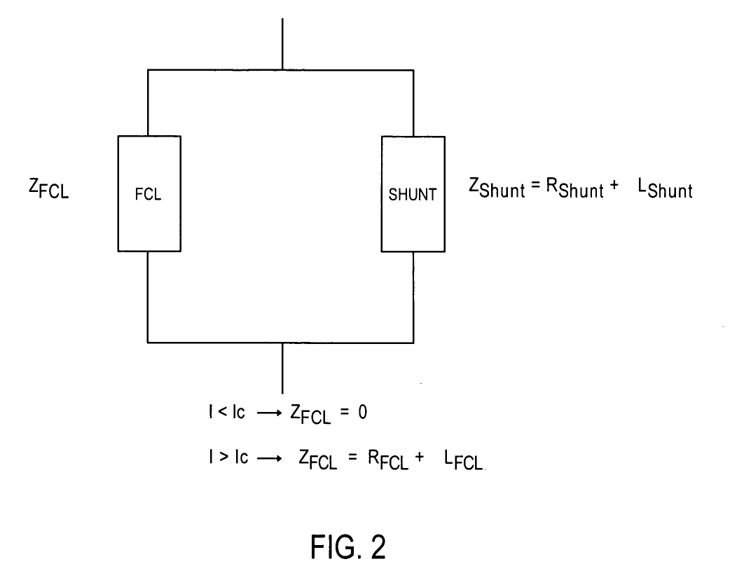

FIG. 2 illustrates the equivalent circuit diagram of a typical FCL module. This system consists of two parallel current paths; one is a superconducting path, and the other is a current limiting shunt. The impedance of the superconducting path (Z_{FCL}) is a function of current. In general,
Z_{FCL}=R_{FCL}+ωL_{FCL},
where R is the resistance and L is the inductance of the superconducting component, respectively. For non-conductive FCL components, the reactive contribution to the impedance of the superconducting path may be neglected and the impedance of the superconducting path is resistive and a function of the current that passes through the component. For currents less than the critical current, Z_{FCL} is zero. For currents well in excess of the critical current of the system, Z_{FCL} approaches R_{FCL}. Parallel to the superconducting path is the current limiting shunt. The shunt is designed to carry the majority of the current during the fault condition, thus protecting the FCL component from damage, and typically consists of resistive and/or inductive components. In general,
Zₛₕᵤₙₜ=Rₛₕᵤₙₜ+ωLₛₕᵤₙₜ,
where Rₛₕᵤₙₜ and Lₛₕᵤₙₜ are the resistance and inductance of the shunt, respectively.

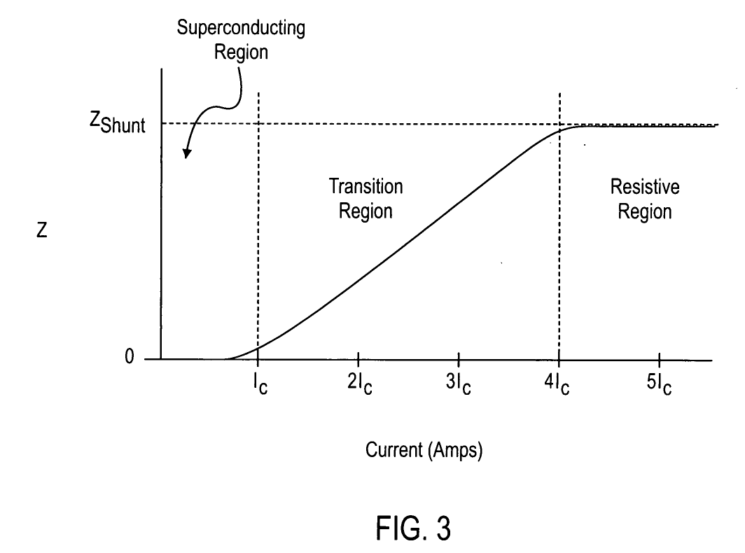

FIG. 3 shows the impedance of the FCL module of FIG. 2 as a function of current. In this example, it is assumed that Z_{FCL} is zero for currents less than the critical current (I_{C}), and that Z_{FCL} is much greater than Zₛₕᵤₙₜ for currents well in excess of I_{C}. An FCL module which minimizes the “transition region” will possess a faster switching characteristic. The “transition region” is characterized by the rapid loss of superconductivity in the FCL component. This rapid transition to the equivalent of a normal metallic state is known as a “quench.” In general, the duration of the quench, and the power dissipated in the FCL component during the quench, may be minimized by:

Increasing the n-value of the FCL component;

Increasing the normal state resistance R_{FCL} of the FCL component.

High temperature superconducting (HTS) ceramic materials can be used as FCL components in the form of rods, thin films, coils, tubes, wire, etc. The materials possess certain properties that make them attractive for use in this application. The properties include:

High superconducting critical temperatures (T_{C}) which allow for operation of the FCL system at temperatures near 77K.

High normal state resistivities on the order of 100 μΩcm at 100K.

High heat capacity that allows the material to absorb a significant amount of heat during the quench without a significant increase in temperature. The HTS ceramics also possess certain physical characteristics that are less satisfactory for use in an FCL system. In particular:

The HTS materials are brittle ceramics. Thermal and mechanical stress, which necessarily occurs during the quench, may produce micro-cracks in the material. These micro-cracks significantly impede the flow of supercurrent in the FCL component and thus degrade the operation of the system.

A low thermal conductivity on the order of 0.01 W/(cm K) at 77K. The low thermal conductivity of these materials makes them susceptible to “hot spot” formation during the quench because the heat does not flow quickly through the material. The thermal runaway at the “hot spot” can cause catastrophic failure of the FCL component.

The HTS materials are Type II superconductors. As such, magnetic flux penetrates the material under high current conditions, producing vortices with normal cores. The movement of these vortices produces resistive heating in the material during the quench. This results in a large thermal load during the switching of the FCL.

Magnesium diboride (MgB₂) displays superconductive properties at low temperatures. Similar to HTS ceramic materials, MgB₂ can be used as FCL components in the form of rods, thin films, coils, tubes, wire, etc. Magnesium diboride possesses certain properties that make it attractive for use in this application. The properties include:

A relatively high superconducting critical temperature (T_{C}) that allows for operation of the FCL system at temperatures below 40K.

A thermal conductivity that is approximately ten times greater than HTS materials.

Magnesium diboride also possesses certain physical characteristics that are less satisfactory for use in an FCL system. In particular:

A relatively low normal state resistivity on the order of 2 μΩcm at 40K. This means that a much longer length of material must be used relative to HTS ceramics to maintain a high R_{FCL} in the FCL component.

A low heat capacity. This means that the temperature of the material will increase significantly with the heat input during the quench.

MgB₂, like HTS materials, is a brittle ceramic and thus subject to cracking from thermal and mechanical stress. However, supercurrent flow in MgB₂ is known to not be significantly reduced by cracks and grain boundaries as the HTS ceramics.

MgB₂, like HTS materials, is a Type II superconductor, and the movement of vortices during the quench will produce resistive heating in the material.

Both HTS materials and magnesium diboride possess certain advantages and disadvantages for use as the active FCL component in an FCL system.

A particularly useful superconducting material for use in an FCL system would possess the following properties:

1) The material would have a high n-value (e.g., >10). Preferably the n-value can be tailored to the specific application and modified through the appropriate choice of materials.

2) A quench mechanism that generates very little resistive heating.

3) A high resistivity normal state such that the fault current can be carried primarily by the shunt in the FCL module.

4) A high thermal conductivity to prevent thermal runaway at any “hot spots” which develop during the quench.

5) High resistance to thermal and mechanical stress. The material should not crack or degrade easily.

Materials and Compositions

Superconductor Metal Matrix Composites (SMMC) components are fabricated by mixing a superconductor powder with a metal (powder or liquid) and forming the composite mixture into a bulk component (bar, rod, plate, coil, etc.) using well-known techniques such as cold or hot isostatic press methods. Details of SMMCs are described in U.S. Pat. No. 6,586,370 which is incorporated by reference herein.

The intimate contact between the superconductor particles and the metal results in a composite material with bulk superconducting properties at temperatures below the superconducting critical temperature of the superconductor particles. The superconductive properties of the composite are enhanced if the metal possesses both a large electron-phonon interaction and a large electron mean free path at temperatures less than the critical temperature of the superconductor.

The mechanical properties of the composite material may be improved relative to the mechanical properties of a brittle superconductive material by using metals that are ductile and malleable in the SMMC.

The use of SMMC components in FCL systems provides for many advantages over both HTS ceramic components and magnesium diboride components. In particular:

(1) “N-Value” Engineering of SMMCs

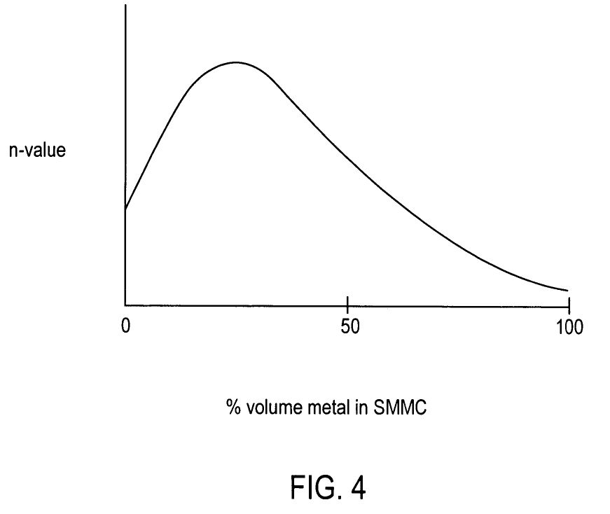

FIG. 4 displays the general behavior that is observed in SMMC materials with superconductor particles in the range of 1 to 50 microns in diameter. The n-value of these composites is a strong function of the % volume of metal in the composite, and tends to have its maximum between 10 to 30% by volume metal. The peak n-value of a given SMMC depends on the particle size distribution of the superconductor particles and the electron-phonon interaction and electron mean free path of the metal.

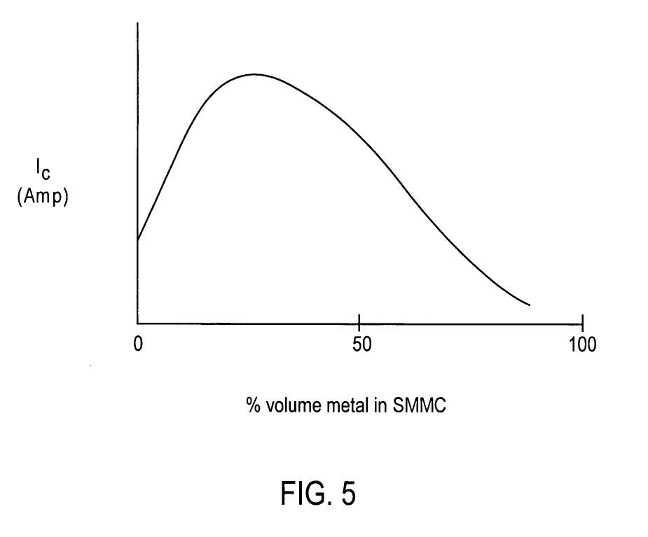

A similar dependence is observed, in that the variation in the critical current of the SMMC is a function of the % volume of metal in the composite. This is shown in FIG. 5. In general, n-values and critical currents for a given composite tend to peak near the same % volume metal.

Specific superconducting applications require certain minimum n-values in the superconducting components. The use of SMMCs allows for the design of a superconducting material with an n-value appropriate for the system. FCL systems, for example, require high n-values to achieve fast switching characteristics. Thus, an FCL system may be fabricated using an SMMC with a % volume of metal between 15 and 40%. Superconducting motors, however, may require lower n-values to achieve system stability under a variety of load conditions. These lower n-values may be achieved, for example, by increasing the % volume metal in the SMMC.

(2) SMMC Quench Mechanism

Type I and Type II superconductors display dramatically different behaviors in applied magnetic fields. Ginzburg Landau (GL) theory is a semi-phenomenological description of superconductivity that describes well the magnetic properties of superconductors. In GL theory, κ=λ_{L}/ξ, where XL is the London penetration depth and ξ is the coherence length of the superconducting Cooper pairs. Type I and Type II behavior is characterized by:
κ<2^{-0.5} Type I
κ>2^{-0.5} Type II

The magnitude of the ratio of the London penetration depth to the superconducting coherence length in superconductors profoundly affects the properties of the material in applied magnetic fields. For example, if a Type I superconductor is cooled to below T_{C} in zero magnetic field, there are zero surface currents in the material. When an external magnetic field is applied to the sample, superconducting surface currents are induced in the material which exactly screen the applied magnetic field. For magnetic field strengths less than the critical magnetic field H_{C}, the magnetic field within the superconductor is attenuated over the distance λ_{L}. At higher field strengths, the induced currents exceed the critical current of the material, and an abrupt transition occurs which drives the material into the normal metallic state. The transition occurs at H_{C} of the Type I superconductor.

In Type II superconductivity, the behavior of the material in low applied magnetic fields is similar to Type I behavior, and surface currents effectively screen the applied magnetic field. As the field strength increases, however, magnetic flux lines begin to penetrate the bulk of the superconductor. The magnetic field strength at which this flux penetration occurs is H_{C1}, the first critical magnetic field. As mentioned previously, for applied magnetic fields less than H_{C1}, the material behaves much like a Type I superconductor. As the applied field strength increases above H_{C1}, however, the material remains in the superconducting state and allows magnetic flux vortices to penetrate the material. As the field strength increases, so does the density of the magnetic flux vortices in the material. These vortices are characterized by a normal metallic core surrounded by circulating supercurrents. The movement of these vortices is referred to as “flux flow” and produces a finite resistance in the otherwise superconducting material.

With increasing magnetic field strength, the magnetic vortex density increases to the level at which no additional vortices may penetrate the material. At that second critical magnetic field H_{C2}, the Type II superconductor reverts back to the normal metallic state.

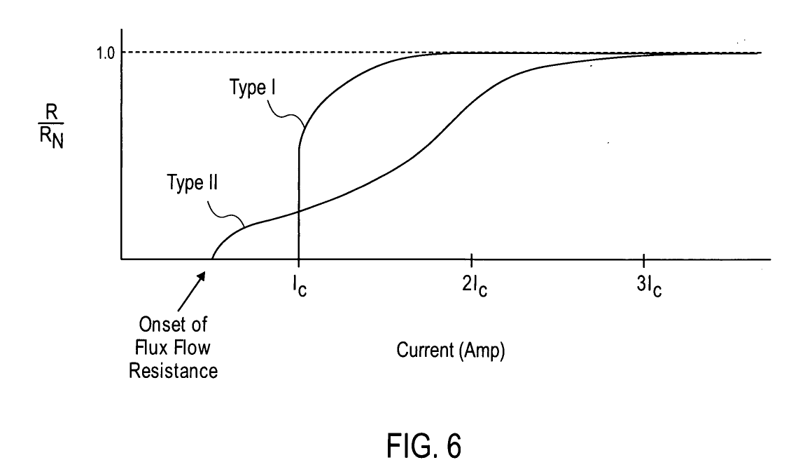

In an FCL component, the response time of the component is a strong function of the magnetic field behavior of the superconductor. In a current-carrying application, the current itself generates a magnetic field at the sample, thus inducing surface currents in the bulk superconductor. This has a profound affect on the manner in which normal metallic resistance begins to appear in the material during the quench. FIG. 6 shows the resistance of a Type I and Type II superconductor as a function of current (FIG. 6 is adapted from Introduction to Superconductivity, M. Tinkham). In Type I behavior, the resistance of the material is essentially zero up to I_{C}, at which point the resistance increases abruptly and approaches R_{N}, the normal metallic state resistance of the material. In Type II superconductors, a finite resistance appears at I_{C1} as magnetic flux lines begin to penetrate the material and flow. This appearance of flux flow resistance produces additional i²R in the FCL component and contributes to the thermal runaway of the system. Clearly, Type I behavior is desired for fast switching properties of FCL systems.

Type I and Type II properties of a superconductor are, in general, intrinsic characteristics of the material. Type I materials tend to be elemental superconductors, with low critical fields and temperatures. Type I materials can be made into Type II materials by adding impurities or other electron-scattering centers to the material. Type II materials, with high critical magnetic fields and higher critical temperatures, are the most practical from an engineering point of view. Unfortunately, it is not possible to engineer Type I behavior in a Type II superconductor while maintaining the high critical currents and high magnetic field properties.

Both HTS ceramic superconductors and magnesium diboride are Type II superconductors. As such, they are susceptible to catastrophic resistive flux flow heating during the quench of an FCL component.

SMMC components can be fabricated with a mixture of Type I and Type II superconductors. The superconductor particles which comprise the SMMC are, in general, Type II superconductors, as they possess higher critical temperatures and critical magnetic fields. The conductive metal component of the SMMC is usually a ductile metallic material with Type I behavior at sufficiently low temperatures.

It is known that supercurrent flow in these composites is limited by the properties of the Type I metal (M. J. Holcomb, “Supercurrents in magnesium diboride/metal composite wire”, Physica C 423 (2005) 103-118). The high critical temperature of the SMMC, however, is determined by the high critical temperature of the Type II material. Thus, by using a mixture of high T_{C} Type II superconductor and a Type I superconductor, it is possible to fabricate an FCL component with both a high critical temperature and high switching speed during the quench.

For example, an FCL component may be fabricated using magnesium diboride particles as the Type II material, and gallium metal as the Type I material in the SMMC. Other candidate Type I materials with large electron-phonon interactions and long electron mean free paths include Bi, Pb, Nb, In, Sn, Hg, and certain alloys of these materials.

Depending on the desired properties, the SMMC FCL component may also be fabricated using Type II materials exclusively. For example, an FCL component may be fabricated using magnesium diboride particles as the high T_{C} Type II material, and a BiPb alloy metal as the ductile Type II metallic material in the SMMC. Other candidate Type II materials with large electron-phonon interactions and long electron mean free paths include alloys of Bi, Pb, Ga, Nb, In, Sn, and Hg.

Candidate metallic materials for use in the SMMC are evaluated on the basis of chemical compatibility with the superconductor particles, the resistivity of the material in the normal metallic state, the electron mean free path length in the normal state, the electron-phonon interaction, the carrier density of the material, materials cost, and other factors.

In general, the combination of a Type II superconductor powder with a Type I metal results in an FCL component with a much improved switching characteristic during the quench state of the system.

(3) Highly Resistive Normal State Properties of SMMCs

In the FCL module displayed in FIG. 2, the current is directed through different branches of the parallel circuit depending on the magnitude of the fault current. For currents less than I_{C}, essentially all current passes through the superconducting FCL component. As the current exceeds I_{C}, the current is redirected through the shunt path of the FCL module. This current redirection occurs when the FCL component undergoes a quench to the equivalent of a normal metallic state. For this current redirection to occur, the normal metallic state impedance of the FCL component must be much larger than the current limiting impedance of the shunt. If this is the case, the vast majority of the fault current will pass through the shunt and thus not damage the FCL component due to i²R heating.

HTS ceramic materials are very resistive in the normal metallic state at temperatures above T_{C}. In general, these materials possess resistivities in excess of 100 μΩcm at temperatures above 100K. In comparison, metals typically have resistivities on the order of 0.01 to 1.0 μΩcm at these temperatures.

Magnesium diboride has a much lower intrinsic resistivity than the HTS ceramics. Typical values for the normal state metallic resistivity of MgB₂ at 40K are on the order of 0.3 μΩcm. Thus, it is necessary to use either longer lengths (or a smaller cross-section) of magnesium diboride to achieve the same normal state resistance as an FCL component fabricated using HTS ceramic materials.

By definition, the resistance R of a conductive component with an ideal geometry (i.e., a bar, rod, plate, etc.) is given as:
R=(ρl)/A,
where ρ is the resistivity of the material, l is the length of the component, and A is the cross-sectional area of the component. A convenient method to increase the resistance of a conductive component is to make it longer (increase l) and make it thinner (decrease A).

If the conductive component is a superconductor, the cross-sectional area A determines the maximum critical current of the component, and l and A determine the normal metallic state resistance of the component with a quench. Typically, FCL components are designed by adjusting A until the required I_{C} is achieved and increasing l to a length at which an appropriate R_{N} is reached.

Since magnesium diboride possesses a much lower p than the HTS ceramics, it is necessary to fabricate a much longer length of the material in the FCL component in order to have the same normal state resistance as an all-HTS ceramic FCL component, assuming the HTS ceramic and the magnesium diboride have comparable critical current densities.

Alternatively, SMMC FCL components with high normal metallic state resistances may be fabricated by combining superconductor particles with highly resistive metals. In general, this can be achieved by combining the superconductor particles with metallic alloys instead of pure elemental metals. A balance must be maintained, however, because the use of alloys as the metal matrix in the SMMC will reduce the electron mean free path in the metal. This reduced electron mean free path may reduce the magnitude of the critical current density of the SMMC.

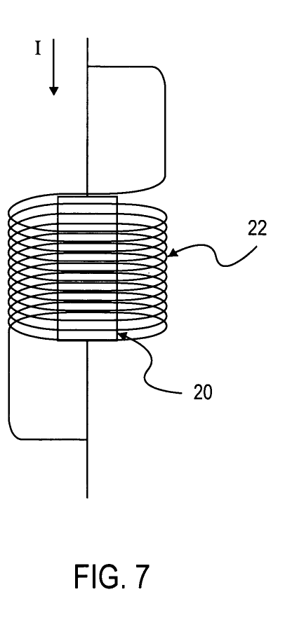

A particularly novel FCL component design takes advantage of the fact that the resisitivity of certain materials increases dramatically in the presence of an applied magnetic field. This phenomenon is called magnetoresistance. The particular SMMC used to fabricate a magnetoresistive FCL component consists of superconducting particles mixed with a conductive material that displays a high degree of magnetoresistivity. FIG. 7 shows a schematic of an FCL component 20 which takes advantage of the magnetoresistance of the conductive metal matrix in the SMMC. In this case, the FCL component 20 is located within the core of a solenoid 22, which is the parallel shunt path of the FCL component 20. For currents less than I_{C}, all current flows through the superconducting FCL component 20. As the current levels exceed I_{C}, the current begins to flow through the solenoid 22 and generates a magnetic field. With increasing currents, the FCL component 20, which has already undergone a quench, is immersed in a high magnetic field that then further increases the normal metallic state resistance of the FCL component 20 due to the high magnetoresistance of the matrix metal. In some cases, the orientation of the solenoid 22 with respect to the FCL component 20 may further increase the resistance of the FCL component 20.

Candidate materials include all magnetoresistive conductive materials and metallic materials with large Hall coefficients. In addition, these materials must also possess the minimum properties (i.e., large electron-phonon coupling and long electron mean free path) for use as the conductive metal component of superconductor metal matrix composites.

Bismuth metal, with large electron-phonon coupling, long electron (hole) mean free paths, and strong magnetoresistive properties, is a particularly good choice as the matrix metal in magnesium diboride-based SMMC materials.

(4) High Thermal Conductivity of SMMCs

During the quench of an FCL component, there is a certain amount of i²R power dissipated in the component as the system redirects the fault current to the parallel resistive shunt. This power results in significant heat input to the FCL component, which may result in a significant increase in the temperature of the FCL component. The subsequent cooling of the FCL component depends on the thermal conductivity κ of the SMMC material. Low thermal conductivities lead to the buildup of excess heat during the quench, and this may lead to the formation of thermal “hot spots” in the FCL component. These “hot spots” produce high thermal and mechanical stress in the material, which may lead to crack formation and ultimately the catastrophic failure of the FCL component.

Referring to Table I, HTS materials are seen to possess relatively low thermal conductivities at 77K. Because of this and the flux flow resistance described earlier, these materials are susceptible to the formation of local “hot spots” during the quench of the FCL component. Magnesium diboride possesses a thermal conductivity nearly an order of magnitude larger than HTS materials, and thus can conduct heat away from the FCL component quickly. Unfortunately, as seen in Table I, the specific heat capacity C_{P} of magnesium diboride is approximately 30 times less than the HTS ceramics, and thus the heat that is input to the magnesium diboride FCL component results in a much larger increase in the temperature of the component versus HTS ceramics. Ideally, FCL components should possess both high thermal conductivities (to conduct heat away during the quench) and high heat capacities (to minimize the temperature increase with the inevitable heat input during the quench).

TABLE I

| | T_{C} | T | CP | κ | JC | ρ |
|---|---|---|---|---|---|---|
| | (K) | (K) | (J/cm³ K) | (W/cm K) | (A/cm²) | (μΩ cm) |
| HTS Ceramic | 90 | 65 | 0.63 | 0.01 | 4,000 | >100 |
| | | | (65 K) | (77 K) | (65 K) | (100 K) |
| MgB₂ | 40 | 27 | 0.02 | ˜0.10 | 40,000 | ˜2 |
| | | | (27 K) | (40 K) | (27 K) | (40 K) |
| Gallium | — | — | 0.27 | 3.89 | — | ˜0.17 |
| | | | (27 K) | (27 K) | | (27 K) |
| MgB₂/Ga SMMC | 38 | 27 | 0.1 | 1.24 | 8,000 | ˜20 |
| (30% by vol.) | | | (27 K) | (27 K) | (27 K) | (40 K) |

As shown in Table I, the heat capacity and thermal conductivity of SMMC materials is a function of both the materials properties of the superconductor particles and the conductive metal matrix. For example, MgB₂/Ga SMMC with 30% by volume Gallium metal possesses a heat capacity five times greater than pure magnesium diboride and a thermal conductivity nearly 100 times greater than HTS ceramics. These properties can be adjusted by changing the % volume and type of conductive metal in the SMMC.

(5) Crack-Resistant SMMC Components

Both HTS ceramics and magnesium diboride superconducting materials are ceramics. As such, they are susceptible to fracture resulting from thermal and mechanical stress experienced during the quench of an FCL component. Micro-cracks and fractures in these materials result in degraded supercurrent transport properties of the component and may result in the catastrophic failure of the system.

SMMC FCL components, which are combinations of brittle superconductor particles and ductile matrix metals, are much more resistant to crack propagation than ceramics. Because cracks do not propagate effectively through the soft metal matrix material, the SMMC is fundamentally a mechanically strong, fracture-resistant material. This property is especially advantageous in an FCL application where the FCL component must withstand very large mechanical and thermal stresses.

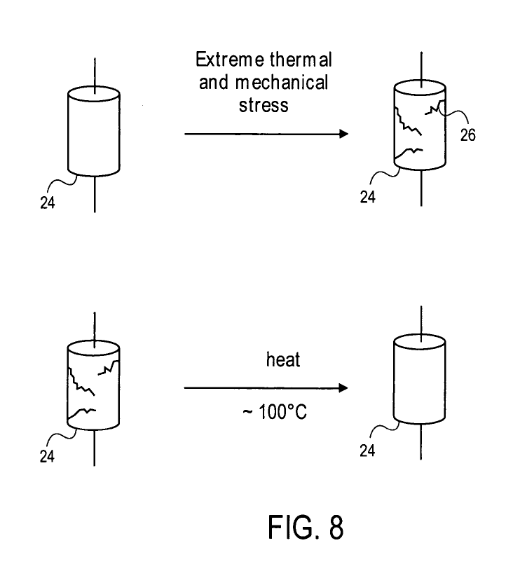

Another advantage of the SMMC FCL component architecture results from the use of relatively low melting point metal matrix materials. As an example, consider the MgB₂/Ga FCL component 24 shown schematically in FIG. 8. It is possible that after several quenches the FCL component 24 may develop minor fractures 26. These fractures 26, if left untreated, may result in the failure of the FCL component 24 during the next quench. Because Gallium metal melts at approximately 30° C., it is possible to “heal” the micro-cracks in the FCL component 24 by simply warming the SMMC up to a temperature in excess of the melting point of the metal matrix. This annealing process then restores the FCL component 24 to its original condition.

This low-temperature “healing” property is unique to SMMC materials. HTS ceramics must be heated in an oxygen-rich atmosphere at temperatures in excess of 800° C. to recover the properties of the material. Magnesium diboride can reform quickly at temperatures in excess of 600° C., but loses Mg metal from the crystal structure easily and therefore must be heated in an Mg-rich atmosphere.

The micro-cracks in an MgB₂/Ga SMMC may be dramatically reduced by heating the SMMC at temperatures greater of 30° C. and well below 600° C., the temperature at which magnesium diboride begins to lose significant amounts of magnesium. Similar behavior is expected from SMMCs fabricated with other metal matrix materials.

In general, SMMC materials offer distinct advantages over both HTS ceramics and magnesium diboride superconductor materials when used in FCL applications. In summary, the use of SMMC technology allows for:

(1) The n-value engineering of the FCL component and the ability to design materials with n-values well in excess of 10, typically at least 15 at 15K.

(2) A quench process that reduces the i²R heating of the component by minimizing the flux flow resistance of the material.

(3) A highly resistive normal state that dramatically reduces the fault current flow through the “quenched” FCL component.

(4) The use of magnetoresistive metal matrix materials and a parallel shunt path in the form of a solenoid to increase the resistance of the FCL component dramatically during the fault.

(5) Thermal conductivity and heat capacity engineering of the material to allow for the control of the thermal properties of the FCL component.

(6) A robust, crack-resistant composite material capable of withstanding repeated quench cycles with little or no degradation of its current-carrying properties.

(7) An FCL component with the ability to “heal” micro-cracks at temperatures well below the annealing or melting temperatures of the superconductor particles in the SMMC.

Example of an FCL-Protected Application

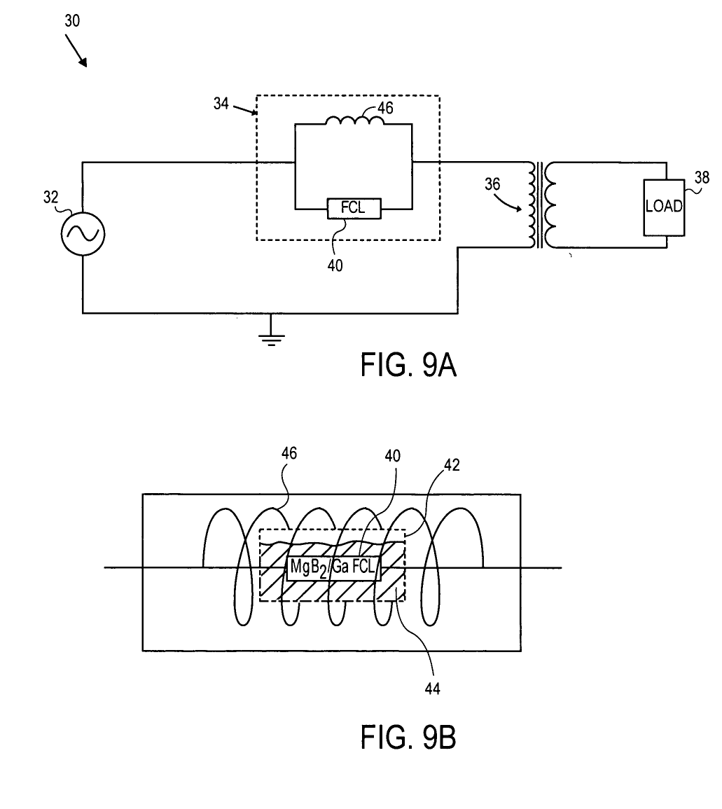

FIGS. 9A and 9B illustrate a circuit 30 with a single-phase FCL protected application. The circuit 30 includes an AC power supply 32, an FCL module 34, and a driven side of a transformer 36 in series. The circuit 30 further includes a load 38 located in series with a load side of the transformer 36. The FCL module 34 protects the transformer 36 from fault currents which may occur in the AC power supply 32.

The FCL module further includes a tank 42 and liquid H₂ 44 in the tank 42. An MgB₂/Ga FCL component 40 is loaded in the liquid H₂ 44 maintained at a temperature below the T_{C} of MgB₂ (˜40K). Preferably, the FCL component 40 will be cooled to temperatures between 20K and 30K. Convenient cryogenic temperatures in this range are liquid hydrogen (20K) and liquid neon (27K). The FCL module 34 further has an impedance provided by a coil 46 in parallel with the FCL component 40. The coil 46 in parallel to the FCL component 40 does not necessarily require cooling to low temperature and may, in fact, be located outside the cryogenic dewar.

Under normal operating conditions of the grid, the impedance of the FCL module 34 is zero, and power is delivered to the load 38 through the transformer 36. During a fault, the impedance of the FCL module 34 increases rapidly. This attenuates the magnitude of the fault current and protects both the transformer 36 and the load 38. After the fault passes, the impedance of the FCL module 34 returns to zero and all current passes through the superconducting branch of the FCL module 34.

MgB₂/Ga FCL Rod

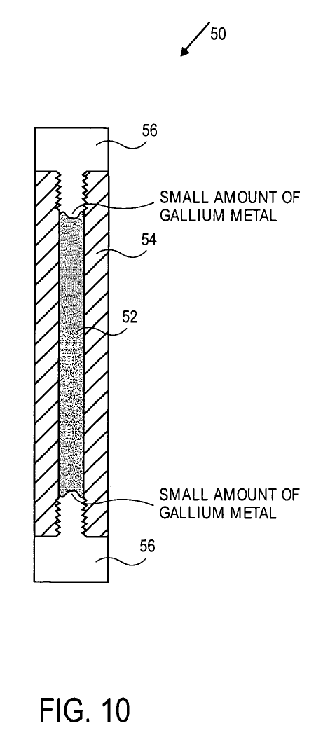

FIG. 10 illustrates an MgB₂/Ga SMMC FCL rod 50 according to an embodiment of the invention. A 20% by volume gallium SMMC FCL rod 50 may be fabricated using the following method:

(1) 12.7 grams of MgB₂ superconducting powder particles and 11.6 grams of liquid or solid gallium metal are combined in a planetary ball mill under an inert atmosphere (80 ml vial) with five 10 mm diameter WC balls and one 20 mm diameter WC ball.

(2) The composite powder 52 is milled for a total of two hours at 500 RPM. A process control agent may be used during the milling process if there is significant cold welding. The use of process control agents is well-known in the field of mechanical alloying.

(3) The milled powder is heated under inert atmosphere at 450° for 15 hours to improve the superconducting fraction of the material. Other combinations of time and temperature may improve the superconducting fraction of the material.

(4) As illustrated in FIG. 10, the composite powder 52 is packed using a ramrod method into a G10 tube 54 affixed with copper current leads 56 on opposing ends. Powder-packing densities in excess of 90% may be achieved using this method.

In this example, the first copper current lead 56 is screwed into one end of the insulating G10 tube 54 and a small amount of gallium metal is added to the end. The tube assembly is then filled with MgB₂/Ga composite powder 52. The filling is accomplished by adding a small amount of powder to the tube and then compressing the powder by inserting a ram rod into the tube and pressing the whole assembly in a hydraulic or hand-operated arbor press. After the G10 tube 54 is filled with the composite powder 52, an additional drop of liquid gallium is added on the top of the compressed SMMC powder and the final copper current lead 56 is screwed in place.

This example describes an MgB₂/Ga FCL rod 50 with an insulating G10 tube 54. Alternative designs may use conductive metal tubes instead of the G10 tube 54. An MgB₂/Ga FCL rod with a conductive metal tube is described well by the equivalent circuit diagram shown in FIG. 2. Here the resistive shunt is the conductive metal tube which contains the compressed SMMC powder.

MgB₂-Based SMMC FCL with Hybrid HTS Current Leads

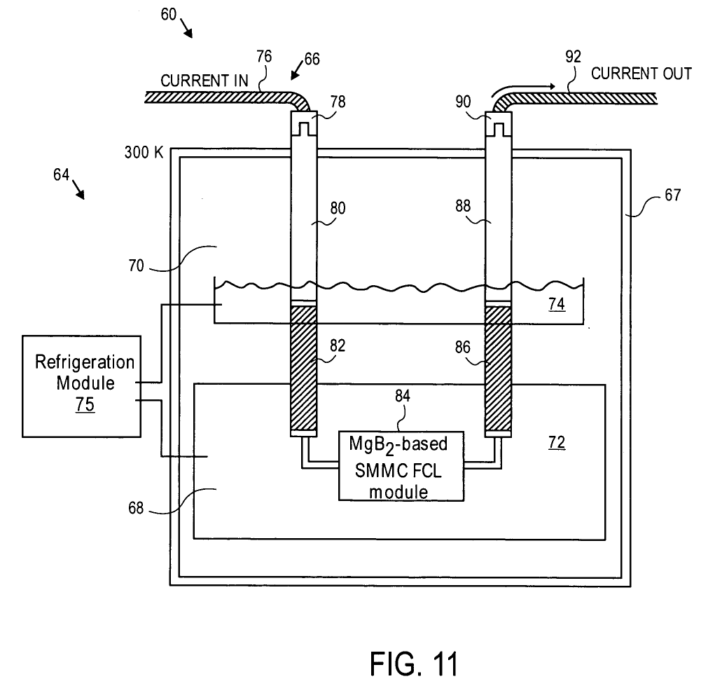

FIG. 11 shows a schematic of an MgB₂-based SMMC FCL system 60 with hybrid HTS current leads. This hybrid design takes advantage of the very low thermal conductivity of the HTS ceramic materials to dramatically reduce the refrigeration load at low temperature.

The FCL system 60 includes a refrigeration system 64 and a circuit 66.

The refrigeration system 64 includes an enclosure in the form of a cryogen tank 67 having lower and upper regions 68 and 70, respectively, hydrogen vapor 72 in the lower region 68, and at about 20K (or alternatively, helium vapor at any temperature above 4.2K, or hydrogen liquid at 20K, or neon vapor above 27K, or neon liquid at 27K), and liquid nitrogen 74 in the upper region 70 at between 66K and 77K, and a refrigeration module 75 to maintain the hydrogen vapor 72 and the liquid nitrogen 74 at their respective temperatures.

The circuit 66 includes a power cable 76, a terminal 78, a current section 80, an HTS section 82, an MgB₂-based SMMC FCL module 84, an HTS superconductor section 86, a current section 88, a terminal 90, and a power cable 92 sequentially in series after one another. The terminals 78 and 90 are located outside the cryogen tank 67. The current sections 80 and 88 extend into the top of the cryogen tank 67. An interface between each current section 80 or 88 and a respective HTS section 82 or 86 is located within the liquid nitrogen 74. Lower ends of the HTS superconductor sections 82 and 86, together with the MgB₂-based SMMC FCL module 84 are located in the hydrogen vapor 72.

In this design, current flows into and out of the FCL system 60 of the module 84 through hybrid high-current leads comprised of a copper section of the current section 80 and an HTS ceramic section of the HTS superconductor section 82. The copper section of the current section 80 may be liquid or vapor-cooled, and it is optimized in cross-sectional area to minimize the heat leak to the refrigeration stage cooled at approximately 77K. At the 77K stage, the copper current section 80 is attached, via a low resistivity joint, to the bulk ceramic HTS section 82. The HTS section 82 may be in the form of a bar, tube, cylinder, plate, etc. The HTS section 82 is designed to have a very low thermal conductivity, thus there preferably should not be any metallic shunt connecting the copper section 80 to the low-temperature lower region 68 of the FCL system 60. The HTS section 82 terminates in the low-temperature lower region 68 of the FCL system 60, where it connects to the MgB₂-based SMMC FCL module 84 with a very low resistivity contact. Preferably, the contact between the HTS section 82 and the MgB₂-based SMMC FCL module 84 is a fully superconducting contact. The FCL module 84 consists of an MgB₂-based SMMC component in parallel with a current limiting shunt resistance as described previously and shown schematically in FIG. 2. After passing through the FCL module 84, the current then passes through the HTS section 86, the copper current section 88, and passes out of the system 60.

For currents less than the critical current of the FCL module, the current passes through the copper current sections 80 and 88, and the fully superconducting HTS sections 82 and 86, and the fully superconducting MgB₂-based SMMC FCL component (see FIG. 2). In a fault current condition, the current passes through the copper current sections 80 and 88, and through the HTS sections 82 and 86. The majority of the fault current then passes through the current limiting shunt (see FIG. 2). This shunt adds additional impedance to the power grid and attenuates the magnitude of the fault current. In this example, the fault current passes through the HTS sections 82 and 86. Thus, it is important to design the HTS sections 82 and 86 such that the possible fault currents in the particular system do not exceed the critical current of the HTS sections 82 and 86. If the fault current exceeds the I_{C} of the HTS components, it could lead to the catastrophic failure of the FCL system 60, as discussed previously.

TABLE II

| | (Heat Load) | | (Cryocooler Power Consumption) | |
|---|---|---|---|---|
| | (1000 Amps) | | (1000 Amps) | |
| Optimized Copper | ˜35 | W | 400 to 600 | W |
| Current Leads | | | | |
| (300 K −> 77 K) | | | | |
| HTS Ceramic | ˜0.10 | W | 40 to 80 | W |
| Current Leads | | | | |
| (77 K −> 4.2 K) | | | | |
| HTS Ceramic | ˜0.02 | W | ˜20 | W |
| Current Leads | | | | |
| (77 K −> 20 K) | | | | |

Table II shows the refrigeration heat load and the power required to run a cryogenic refrigerator for optimized copper and HTS current leads per 1000 Amps of current carried by the leads. Here, the extremely low thermal conductivity of the HTS ceramics is quite beneficial, as it significantly reduces the refrigeration load at low temperatures. In fact, with these hybrid copper/HTS ceramic current leads, the majority of the heat load arises from the high thermal conductivity of the copper leads which carry the current from room temperature (300K) to approximately 77K.

Estimates of the required heat load and refrigeration power at 20K are also shown in Table II. These values are appropriate for operation of an MgB₂-based SMMC FCL system because the low temperature reservoir of the system will be maintained at approximately 20K to 30K. Assuming an average refrigerator power consumption of 500 W/kA to power a cryocooler at 77K, cooling an all-HTS FCL system to ˜77K would require ˜500 W/kA of current passing through the system. Alternatively, by using hybrid copper/HTS ceramic leads to carry the current from room temperature to an MgB₂-based FCL component operating at 20K, only approximately 520 W/kA would be required to power the cryocooler. Thus, there is only a 4% increase in power consumption with the use of MgB₂-based SMMC FCL components versus a fully HTS ceramic system operating at 77K.

Alternative Design of an MgB₂-Based SMMC FCL

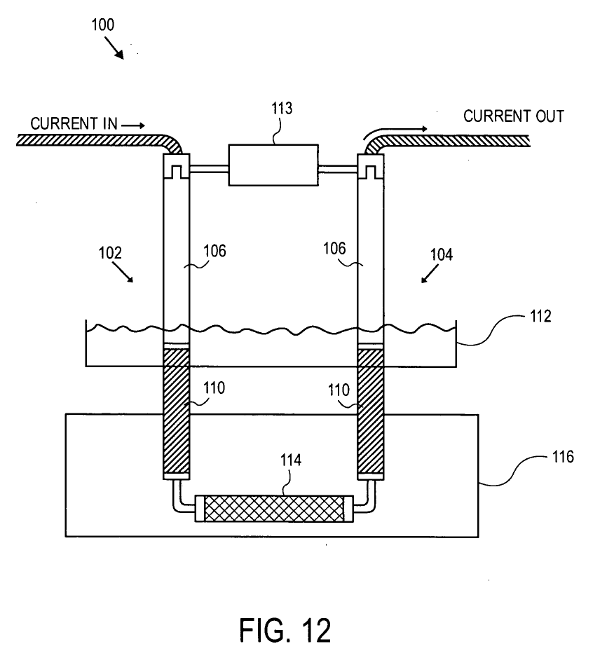

FIG. 12 shows a schematic of an alternative design of an MgB₂-based SMMC FCL system 100 with hybrid HTS current leads. Similar to the previously described FCL system 60, the FCL system 100 takes advantage of the very low thermal conductivity of the HTS ceramic materials to dramatically reduce the refrigeration load at low temperature. In addition, the parallel current limiting shunt resistance of this FCL system 100 is located outside the cryogenic system. This geometry prevents the fault current from potentially damaging the HTS current leads during a fault condition.

In this design, current flows into the FCL system 100 through hybrid high current leads 102 and 104 comprised of a copper current section 106 and an HTS ceramic section 110. No current passes through the current limiting shunt 113 which spans the copper current sections 106 because the impedance of the current limiting shunt 113 is much greater than the impedance of the hybrid copper/HTS ceramic leads 102 and 104 and the MgB₂-based SMMC FCL component 114, combined. The copper section 106 of the current lead 102 or 104 may be liquid or vapor-cooled, and is optimized in cross-sectional area to minimize the heat leak to the refrigeration stage 112, cooled at approximately 77K. At the 77K stage, the copper current section 106 is attached, via a low resistivity joint, to a bulk HTS ceramic section 110. The HTS ceramic section 110 may be in the form of a bar, tube, cylinder, plate, etc. The HTS ceramic section 110 is designed to have a very low thermal conductivity, thus there preferably should not be any metallic shunt connecting the copper current section 106 to the low-temperature region of the system. The HTS ceramic section 110 terminates in the low-temperature level 116 of the FCL system 100, where it connects to the MgB₂-based SMMC FCL component 114 with a very low resistivity contact. Preferably, the contact between the HTS ceramic section 110 and the MgB₂-based SMMC FCL component 114 is a fully superconducting contact. Thus, for current levels below the critical current, the system 100 consists of fully superconducting components below the copper/HTS ceramic contacts. After passing through the FCL component 114, the current then passes through a second HTS current lead 110 and a second optimized copper current section 106 of the hybrid current lead 104 and passes out of the system 100.

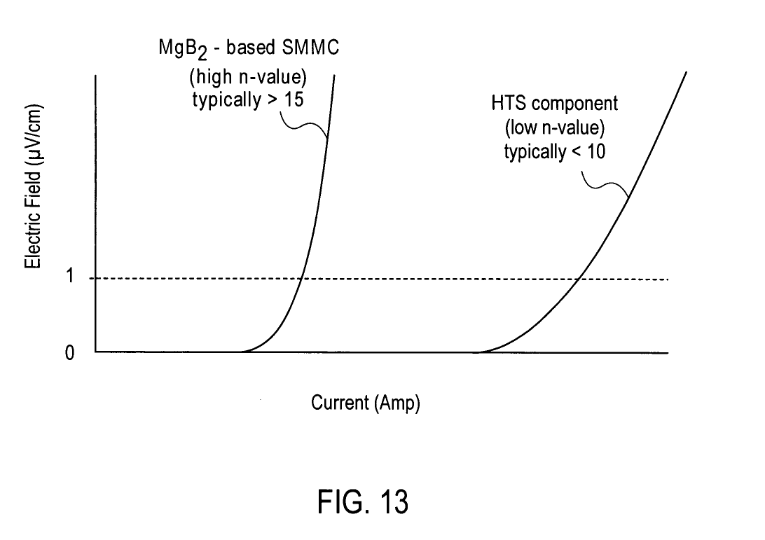

For currents less than the critical current of the FCL module, the current passes through the copper current sections 106, and the fully superconducting HTS ceramic sections 110, and the fully superconducting MgB₂-based SMMC FCL component 114. At the beginning of a fault condition, the current passes through the copper current sections 106, through the HTS ceramic sections 110, and through the MgB₂-based SMMC FCL component 114. As the current level exceeds the critical current of the MgB₂-based SMMC FCL component 114, the resistance of this component 114 increases dramatically, and the majority of the fault current then passes through the current-limiting shunt 113. This shunt 113 adds additional impedance to the power grid and attenuates the magnitude of the fault current. In this example, the majority of the fault current does not pass through the HTS ceramic sections 110, and the HTS ceramic sections 110 remain in the superconducting state during the fault. In order to protect the HTS ceramic sections 110 from possible quenches due to high current surges, the critical current of the MgB₂-based SMMC FCL component 114 must be less than the critical current of the HTS ceramic sections 110. This is illustrated in FIG. 13. By designing the MgB₂-based SMMC FCL component 114 to have a much smaller I_{C}, the component 114 is essentially protecting the fragile HTS ceramic sections 110, and the downstream utility hardware, from damaging fault current levels. In essence, the MgB₂-based SMMC FCL component 114 reverts to a normal state resistance and redirects the damaging current through the resistive current limiting shunt 113 before the current rises to a level which may damage the HTS ceramic sections 110. Thus, it is important to design the HTS ceramic sections 110 such that the possible fault currents in the particular system do not exceed the critical current of the HTS ceramic sections 110.

The system 100 of FIG. 12 is the same as the system 60 of FIG. 11 in all other respects.

In general, a preferred embodiment of an FCL system will possess the following characteristics:

1) Preferably, the system will utilize hybrid copper/HTS ceramic current leads to minimize the refrigeration heat load at temperatures below 77K.

2) Preferably, the system will utilize a superconducting current limiting component consisting of a superconducting composite material with an n-value in excess of 15 at temperatures in excess of 15K.

3) Preferably the superconducting current limiting component will consist of a magnesium diboride-based superconducting metal matrix composite material.

4) Preferably the superconducting current limiting component will consist of a composite material that possesses a thermal conductivity in excess of the HTS materials to prevent the formation of “hot spots” during a fault condition.

5) Preferably the superconducting current limiting component will consist of a composite material that possesses a heat capacity in excess of magnesium diboride to prevent thermal runaway during the fault condition.

6) Preferably the superconducting current limiting component will consist of a composite material that possesses a normal state resistivity in excess of magnesium diboride to effectively redirect the fault current to the resistive current limiting shunt.

7) Preferably, the superconducting current limiting component will be in series with HTS ceramic current leads that possess critical currents (determined using the 1 μV/cm electric field criterion, as is well-known in the art) as least two times the critical current of the superconducting current limiting component.

8) Preferably, the system will utilize a current limiting resistive shunt in parallel with the superconducting current limiting component. The shunt will carry the majority of the current during the fault condition.

9) The current limiting resistive shunt may be in the form of a coil, rod, wire, or other geometry.

10) The current limiting resistive shunt may be located in the cryogen, or mounted outside of the cryogenic environment.

Hybrid Current Limiting System

In order to effectively reduce the current surge during a fault condition in an electrical distribution system equipped with an FCL, the impedance of the FCL during the fault must be significantly larger than the intrinsic impedance of the electrical distribution system.

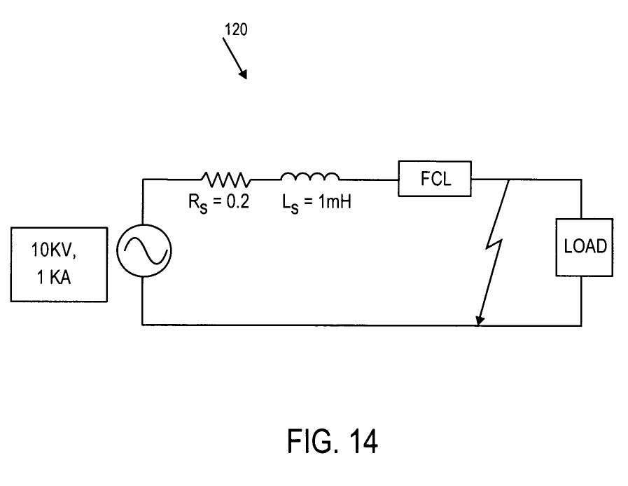

FIG. 14 illustrates a single-phase 10 kV, 1 kA electrical distribution system 120, wherein the source resistance R_{S} and source inductance L_{S} are 0.2 Ω and 1 mH, respectively. The impedance of the electrical grid X_{G} at 60 Hz can be shown to be:
X_{G}={(0.2 Ω)²+[2π60(0.001 mH)]²}^{0.5}=0.43 Ω.

In a fault condition, where power is shorted to ground, for example, the fault current may surge to:
10 kVₚ₋ₚ=7071 V_{RMS}
I_{FAULT}=(7071 V_{RMS})/0.43 Ω˜16,000 Amps.

An FCL system adds impedance to the electrical grid during the fault condition, thus dramatically reducing the magnitude of the fault current surge. For example, assuming the FCL system possesses a resistive impedance of 0.5% for currents in excess of 1 kA, then an approximate magnitude of the fault current in the electric distribution system can be shown to be:
I_{FAULT}==(7071 V_{RMS})/{(0.2 Ω+0.5 Ω)²+[2π60(0.001 mH)]²}^{0.5}
I_{FAULT}=(7071 V_{RMS})/0.8 Ω˜8,900 Amps.
The insertion of a 0.5 Ω resistive impedance in this example reduces the magnitude of the fault current by nearly 50%. If the FCL system possesses a resistive impedance of 5 Ω for currents in excess of 1 kA, the fault current is limited to approximately 1300A.

As discussed previously, in order to increase the normal state metallic resistance of an FCL component, it is necessary to increase the length of the material and decrease the cross-sectional area.

The resistivity of the MgB₂/Ga (30% by volume) SMMC material is approximately 20 μΩcm at 40K. The critical current density of the SMMC at a given temperature below the critical temperature (and magnetic field below the critical magnetic field) determines the physical cross-sectional area of the superconducting composite material used to fabricate the FCL component. For example, if the FCL component must carry 1000A in the superconducting state, and the critical current density of the superconducting composite material is 10,000 A/cm², then the cross-section of the conductor must be larger than 0.1 cm².

This cross-sectional area, along with the length of the FCL component, then determines the resistance of the FCL component in the normal state. For example, a one-meter length of MgB₂/Ga (30% by volume) rod, with a cross-sectional area of 0.1 cm², has a normal state resistance of 0.02 Ω at 40K. A ten-meter length of this rod has a normal state resistance of 0.2 Ω at 40K.

Preferably, an effective FCL component for an electrical distribution grid application possesses a resistance in excess of the source resistance of the electrical distribution grid. In general, this means that long lengths of superconducting materials must be used to fabricate effective FCL components.

Composite powder-in-tube superconducting wires, with HTS ceramics or MgB₂ as the superconducting materials, are attractive for use in an FCL component because very long lengths can be manufactured. These long-length conductors have a high resistance in the normal metallic state, but suffer from other problems associated with the use of a wire in this application. A significant disadvantage of using a wire-based FCL component is that the component is typically formed by winding the wire into a coil. This coil adds an inductive component to the impedance of the system. While in general this is beneficial, as the inductance adds to the impedance of the FCL component during the fault condition, the added inductance also increases the time constant of the system (i.e., the FCL system responds more slowly to the fault condition). In addition, powder-in-tube wire geometry suffers from significant losses under alternating current conditions. These losses arise from the generation of eddy currents in the normal metal sheath of the composite wire. The longer length of the conductor, the more power that is generated due to this alternating current. This phenomenon of AC loss in composite superconducting wire is well-known in the art, and in this application can significantly increase the cryogenic heat load at the operating temperature of the FCL component.

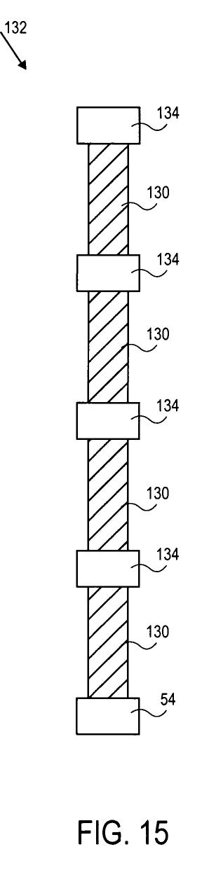

Bulk HTS ceramic rods or tubes are also attractive materials for application in FCL components. To achieve long lengths of these materials, however, it is necessary to assemble many tubes in series, thus increasing the normal state metallic resistance of the FCL component. FIG. 15 illustrates how a series of HTS ceramic tubes 130 must be assembled to increase the resistance of the overall FCL component 132. Between each HTS ceramic tube 130, there is a low-resistance contact to a copper current lead 134. The copper current leads 134 provide for low-resistance contacts between the HTS ceramic tubes 130, but not superconducting contacts. Thus, there is significant i²R loss at the many copper current leads 134 joining the HTS ceramic tubes 130. This also adds a significant refrigeration heat load at the operating temperature of the FCL component 132.

Preferably, the FCL component would consist of a long length of superconducting material (high resistance normal state) arranged in a substantially non-inductive geometry (to maintain a fast response time) which is not susceptible to significant AC loss (i.e., no metal sheath surrounding the superconducting material) and which consists primarily of fully superconducting components (to minimize i²R heating) at the operating temperature of the system.

The following is a design for an FCL component that consists of a long length of superconducting material that is not surrounded by a metallic sheath and is not assembled with non-superconducting contacts at any interface.

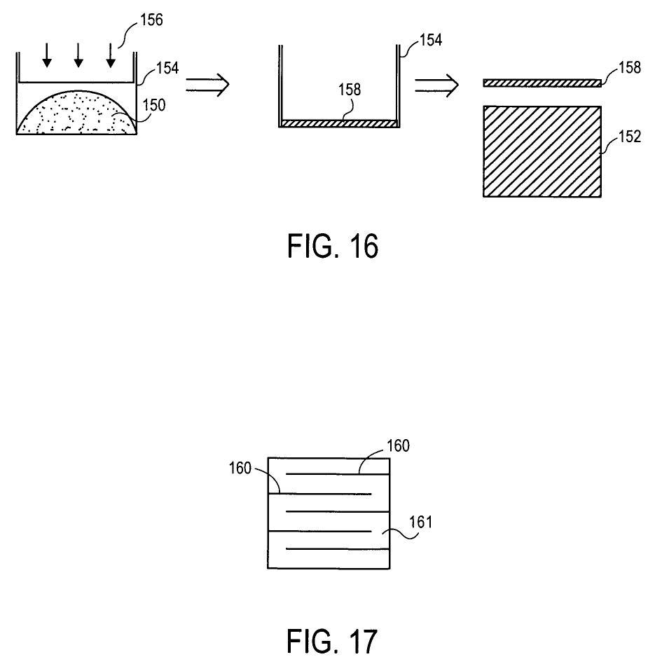

The FCL component is assembled from a series of thin square SMMC plates. In this example, an MgB₂/Ga (30% by volume) SMMC powder is used to make the square plates. FIG. 16 illustrates the method of forming the MgB₂/Ga SMMC powder 150 into a dense thin plate 152. The MgB₂/Ga SMMC powder 150 is placed into a forming mold 154, which is then compressed in a mechanical press 156 into a thin square plate 158. Forming powder into dense bulk parts using hydraulic, mechanical, or isostatic (cold or hot) presses is well-known in the art. Upon removal from the mold 154, the thin square plate 158 is then sliced in an alternating pattern of slits or separations 160 as to create a meandering path 161 of compressed SMMC powder. By cutting the SMMC sheet in this manner, the effective path length of the superconducting composite is increased dramatically.

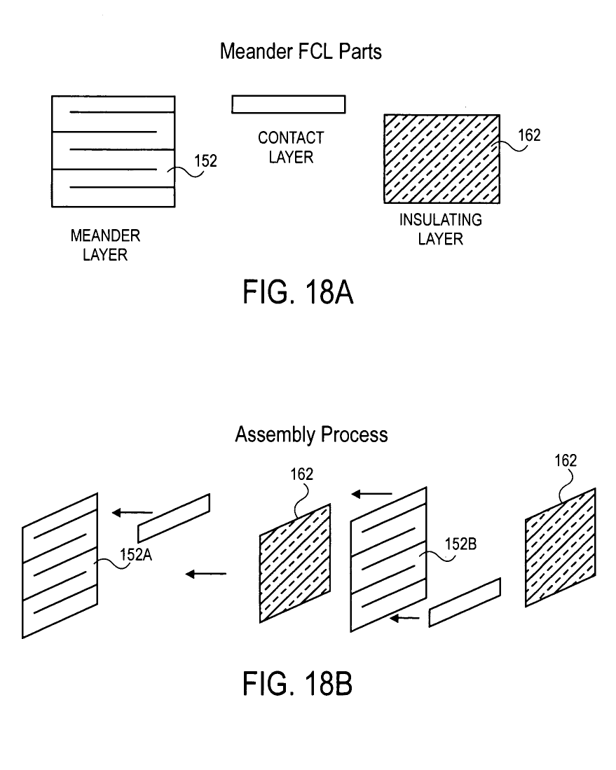

A long-length FCL component is assembled using a series of plates with meandering current paths, inter-plate contact layers, and insulating layers separating the meandering current paths. This process is illustrated in FIGS. 18A and 18B, where a glass plate 162 is used to insulate the meandering current paths of adjacent plates 152A and 152B. The layers formed by the plates 152A and 152B and glass plates 162 may be assembled in a press (hot or cold) and fused together using techniques well-known in the art such as hot pressing, ultrasonic welding, etc.

The process of stacking a number of these layers creates a long path length of the superconducting composite, and thus, a large normal state metallic resistance. This large resistance is achieved in a bulk superconducting material without the use of low-resistance copper contacts, or a metallic sheath surrounding the superconducting material. Thus, an FCL component according to this process does not suffer from the i²R losses found in the series connected HTS FCL rods, or the AC losses found in wire-based FCL components.

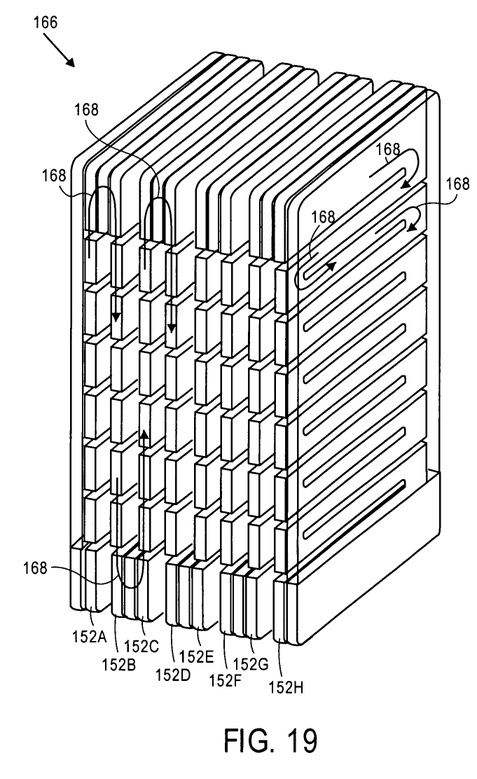

A bulk meander path FCL component 166 is illustrated in FIG. 19. The arrow 168 in FIG. 19 shows the alternating path the current takes as it passes through the layers. The current is meandering in a three-dimensional path, that is, the current meanders through each individual plate (e.g., 152H) and meanders back and forth as it passes from meander plate (e.g., 152A) to meander plate (e.g., 152B) through the contact layers. Because the currents from adjacent paths and plates (e.g., 152A and 152B) are flowing in opposite directions, the internal magnetic fields in this component largely cancel, thus reducing stress on the FCL component 166 in high current conditions, eddy current loss, and the inductance of the FCL component 166.

The critical current, and normal state resistance, of the meander path FCL component 166 can easily be engineered to the particular FCL system specifications. The critical current of the FCL component 166 is determined by the critical current density of the superconducting material, and the cross-sectional area of the meander paths. The normal state resistance of the FCL component 166 is determined by the overall path length of the meandering current path. This resistance is easily increased by increasing the number of meandering current plates 152 in the bulk FCL component 166.

The complete FCL component 160 shown in FIG. 19 may be equipped with different parts in the insulating layers, such as heat fins, which may aid in the cooling of the component during the fault condition.

Other meandering current paths, such as spiral or circular paths, are possible and may be preferred in specific applications.

Hybrid Current Limiting System Using a Meandering Current FCL Component

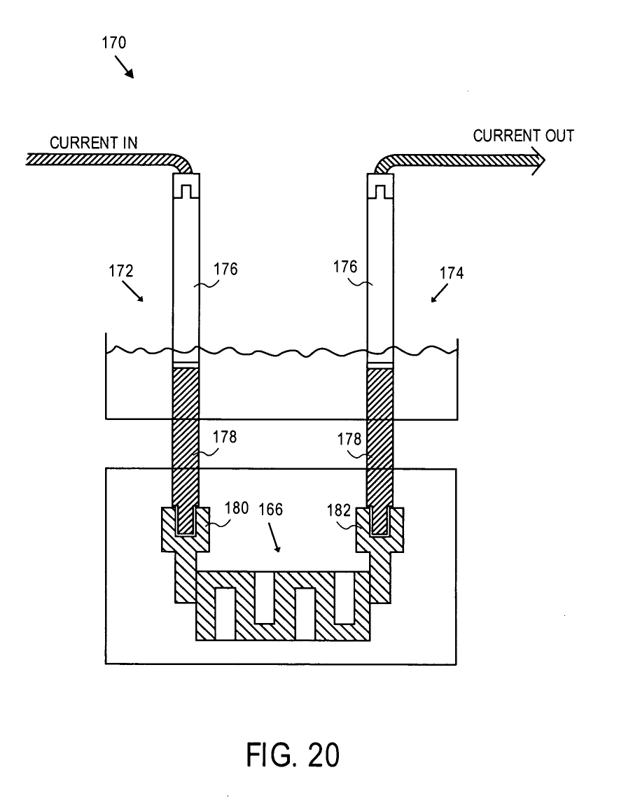

FIG. 20 shows a schematic of an MgB₂-based SMMC FCL system 170 with a meandering current path FCL component 166 and hybrid HTS current leads 172 and 174. This novel hybrid design takes advantage of the high normal state resistance of the meandering current path FCL component 166 to efficiently attenuate the magnitude of the fault current, and the very low thermal conductivity of the HTS ceramic materials to dramatically reduce the refrigeration load at low temperature. In this example, there is no parallel current limiting resistive shunt, and the fault current passes through the meander path FCL component 166 at all times.

In this design, current flows into the FCL system 170 through hybrid high current leads 172 and 174 comprised of a copper section 176, an HTS ceramic section 178, and an MgB₂-based SMMC section 180. The copper section 176 of the current lead 172 may be liquid or vapor-cooled, and is optimized in cross-sectional area to minimize the heat leak to the refrigeration stage cooled at approximately 77K. At the 77K stage, the copper current section 176 is attached, via a low resistivity joint, to a bulk HTS ceramic section 178. The HTS ceramic section 178 may be in the form of a bar, tube, cylinder, plate, etc. The HTS ceramic section 178 is designed to have a very low thermal conductivity, thus there preferably should not be any metallic shunt connecting the copper section 176 to the low-temperature region of the system. The HTS ceramic section 178 terminates in the low-temperature level of the FCL system 170, where it connects to an MgB₂-based SMMC section 180. Preferably, the contact between the HTS ceramic section 178 and the MgB₂-based SMMC section 180 is a fully superconducting contact. The MgB₂-based SMMC section 180 terminates in the low-temperature level of the FCL system 170, where it connects to a meander path MgB₂-based SMMC FCL component 166. After passing through the FCL component 166, the current then passes through a second MgB₂-based SMMC current section 182, a second HTS ceramic section 178, a second optimized copper current section 176, and passes out of the system 170.

For currents less than the critical current of the FCL component 166, the current passes through the copper sections 176, and the fully superconducting HTS ceramic sections 178, and the MgB₂-based SMMC sections 180 and 182, and the fully superconducting meander path MgB₂-based SMMC FCL component 166. In a fault current condition, the current passes through the copper sections 176, through the HTS ceramic sections 178, through the MgB₂-based SMMC sections 180 and 182, and through the meander path MgB₂-based SMMC FCL component 166. Under these high current conditions, the meander path MgB₂-based SMMC FCL component 166 adds additional impedance to the power grid and attenuates the magnitude of the fault current. In this example, the fault current passes through the HTS ceramic sections 178. Thus, it is important to design the HTS ceramic sections 178 such that the possible fault currents in the particular system do not exceed the critical current of the HTS or MgB₂-based SMMC sections 178, 180, or 182. If the fault current exceeds the I_{C} of the HTS or MgB₂-based SMMC current leads, it could lead to the catastrophic failure of the FCL system 170, as discussed previously. Also, the fault current passes through the meander path MgB₂-based SMMC FCL component 166, which is in the resistive state during the fault, and thus will produce significant i²R heating for the duration of the fault.

The system 170 of FIG. 20 is the same as the system 60 of FIG. 11 in all other respects.

The design illustrated in FIG. 20 eliminates, or dramatically reduces, the i²R power loss in the low-temperature region of the FCL system by establishing fully superconducting contacts between the HTS ceramic and the MgB₂-based SMMC materials.

Example: Meander Path FCL with 10 Ω Normal State Resistance at 40K

In this example, an MgB₂-based SMMC powder is used to fabricate a meander path FCL component with a normal state resistance at 40K of 10 Ω and a critical current of 500A at 27K, the temperature of liquid neon. The resistivity of bulk MgB₂/Ga (30% by volume) SMMC is approximately 20 μΩcm at 40K. The critical current density of bulk MgB₂/Ga (30% by volume) SMMC is approximately 8,000 A/cm² at 27K in self-field.

To achieve an I_{C} of approximately 500A at 27K:
Cross-sectional area=(500 A)/(8,000 A/cm²)=6.25×10⁻² cm².

Assuming a meander plate thickness of 0.2 cm:
Meander strip width=(6.25×10⁻² cm²)/(0.2 cm)=0.3125 cm=3.125 mm.

A 20 cm×20 cm, 2 mm thick MgB₂/Ga SMMC square plate is fabricated using powder compression techniques well-known in the art. As illustrated in FIG. 17, 1 mm wide slices are cut in an alternating pattern to generate meander strips that are approximately 3 mm in width. These cuts extend approximately 18 cm from the edge of the plate, leaving approximately 2 cm uncut. Thus, the total width of the meander strip plus the slice is approximately 4 mm, and a total of 50 meander strips may be fabricated from a single 20 cm×20 cm plate. Assuming the meander path is 18 cm in length, and that there are 50 strips per plate, the resistance of each meander plate is:
Plate Resistance=50{[(20 μΩcm)(18 cm)]/(6.25×10⁻² cm²)}=0.29 Ω.
With each meander plate possessing a normal state resistance of ˜0.29 Ω, a stack of approximately 35 plates will give the meander path FCL component a normal state resistance equal to approximately 10 Ω
Alternative Design of a Hybrid Current Limiting System Using a Meandering Current FCL Component

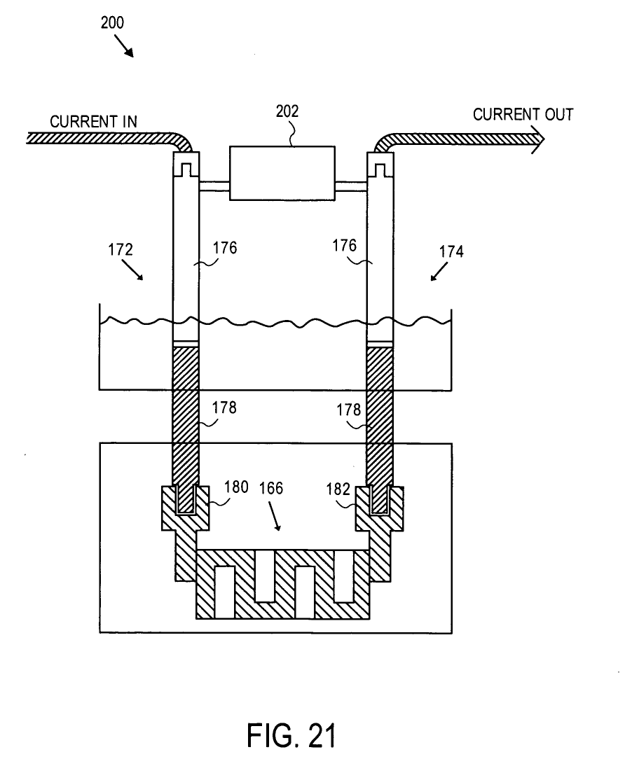

FIG. 21 shows a schematic of an alternative design of an MgB₂-based SMMC FCL system 200 with a meandering current path FCL component 166, hybrid HTS current leads 172 and 174, and MgB₂-based SMMC sections 180 and 182. Similar to the embodiment of FIG. 20, the embodiment of FIG. 21 takes advantage of the high normal state resistance of the meandering current path FCL component 166 to efficiently attenuate the magnitude of the fault current, and the very low thermal conductivity of the HTS ceramic materials to dramatically reduce the refrigeration load at low temperature. In addition, a parallel current limiting shunt resistance 202 is located outside the cryogenic system or in parallel with the FCL component 166. This geometry prevents the fault current from potentially damaging the both the HTS and MgB₂-based SMMC current leads during a fault condition.

In this design, current flows into the FCL system 200 through hybrid high current leads 172 and 174, each comprised of a copper section 176, an HTS ceramic section 178, and an MgB₂-based SMMC section 18. No current passes through the resistive shunt 202 which spans the copper sections 176, because the impedance of the resistive shunt 202 is much greater than the impedance of the hybrid copper/HTS ceramic/MgB₂-based SMMC sections 172 and 174 and the meander path MgB₂-based SMMC FCL component 166, combined. The copper section 176 of the current lead 172 may be liquid or vapor-cooled, and it is optimized in cross-sectional area to minimize the heat leak to the refrigeration stage cooled at approximately 77K. At the 77K stage, the copper current section 176 is attached, via a low resistivity joint, to a bulk HTS ceramic section 178. The HTS ceramic section 178 may be in the form of a bar, tube, cylinder, plate, etc. The HTS ceramic section 178 is designed to have a very low thermal conductivity, thus there preferably should not be any metallic shunt connecting the copper section 176 to the low-temperature region of the system. The HTS ceramic section 178 terminates in the low-temperature level of the FCL system 200, where it connects to an MgB₂-based SMMC current section 180. Preferably, the contact between the HTS ceramic current lead 178 and the MgB₂-based SMMC section 180 is a fully superconducting contact. The MgB₂-based SMMC section 180 terminates in the low-temperature level of the FCL system 200, where it connects to a meander path MgB₂-based SMMC FCL component 166. After passing through the FCL component 166, the current then passes through the MgB₂-based SMMC current lead 182, the HTS current lead 178 of the hybrid current lead 174, the copper current section 176 of the hybrid current lead 174, and passes out of the system 200.

For currents less than the critical current of the FCL module component 166, the current passes through the copper sections 176, the fully superconducting HTS ceramic and MgB₂-based SMMC sections 178, 180, and 182, and the fully superconducting meander path MgB₂-based SMMC FCL component 166. At the beginning of a fault current event, the current passes through the copper sections 176, through the HTS ceramic sections 178, through the MgB₂-based SMMC sections 180 and 182, and through the meander path MgB₂-based SMMC FCL component 166. As the current level exceeds the critical current of the meander path MgB₂-based SMMC FCL component 166, the resistance of this component 166 increases dramatically, and the majority of the fault current is redirected through the current limiting shunt 202. The shunt 202 adds additional impedance to the power grid and attenuates the magnitude of the fault current. In this example, the majority of the fault current does not pass through the ceramic sections 178 and the MgB₂-based SMMC sections 180 and 182. Preferably, both the ceramic sections 178 and the MgB₂-based SMMC sections 180 and 182 remain in the superconducting state during the fault. In order to protect both the ceramic sections 178 and the MgB₂-based SMMC sections 180 and 182 from possible quenches due to high current surges, the critical current of the meander path MgB₂-based SMMC FCL component 166 must be less than the critical current of both the ceramic sections 178 and the MgB₂-based SMMC sections 180 and 182. By designing the meander path MgB₂-based SMMC FCL component 166 to have a much smaller I_{C}, the component 166 is essentially protecting the fragile HTS ceramic section 178, the MgB₂-based SMMC sections 180 and 182, and the downstream utility hardware, from damaging fault current levels. In essence, the meander path MgB₂-based SMMC FCL component 166 reverts to a high normal state resistance during the fault, and redirects the damaging current through the resistive current limiting shunt 202 before the current rises to a level which may damage the other current carrying components of the system 200. Thus, it is important to design the HTS ceramic sections 178 and the MgB₂-based SMMC sections 180 and 182 such that the possible fault currents in the particular system do not exceed the critical current of both the HTS ceramic sections 178 and the MgB₂-based SMMC sections 180 or 182.

The system 200 of FIG. 21 is the same as the system 170 of FIG. 20 in all other respects.

While certain exemplary embodiments have been described and shown in the accompanying drawings, it is to be understood that such embodiments are merely illustrative and not restrictive of the current invention, and that this invention is not restricted to the specific constructions and arrangements shown and described since modifications may occur to those ordinarily skilled in the art.

What is claimed:

1. A fault current limiting system, comprising:
a refrigeration system;
first and second leads; and
a fault current limiting component thermally connected to the refrigeration system so as to be maintained at a cryogenic temperature and having opposing terminals connected to ends of the first and second leads, respectively, the fault current limiting component being made of a superconductor material having an n-value of at least 15 at a temperature of at least 15K.

2. The fault current limiting system of claim 1, wherein the superconductor material includes a plurality of superconductor particles and a metal in proximity to the superconductor particles to be driven to a superconducting state by the superconducting particles to provide a superconducting path from the first lead to the second lead.

3. The fault current limiting system of claim 2, wherein the superconductor particles are made of a Type II superconductor material and the metal is made of a Type I superconductor material.

4. The fault current limiting system of claim 3, wherein the superconductor particles are magnesium and the metal is gallium.

5. The fault current limiting system of claim 1, wherein the fault current limiting component defines a meandering superconducting path.

6. The fault current limiting system of claim 5, wherein the fault current limiting component has a plurality of alternating slits formed therein to define a meandering superconducting path.

7. The fault current limiting system of claim 6, wherein the slits are formed in a manner so that a three-dimensional meandering path is defined.

8. The fault current limiting system of claim 7, wherein the FCL component comprises a plurality of plates, each plate having a plurality of alternating slits formed therein.

9. The fault current limiting system of claim 1, further comprising a shunt with impedance connected between the first and second leads in parallel with the FCL component.

10. The fault current limiting system of claim 1, wherein the refrigeration system includes a cryogenic enclosure, the first and second leads extending into the cryogenic enclosure, a cryogenic fluid located within the cryogenic enclosure, and a refrigeration module connected to the cryogenic enclosure to maintain the cryogenic fluid at a cryogenic temperature, the FCL component being located within the cryogenic fluid.

11. The fault current limiting system of claim 1, comprising first and second cryogenic fluids, the first cryogenic fluid being at a lower temperature than the second cryogenic fluid, the FCL component being located in the first cryogenic fluid, the first and second leads being hybrid leads, each including a high-temperature superconductor section and a metal section, a lower end of the high-temperature superconductor section being located in the first cryogenic fluid, and an upper end of the high-temperature superconductor section and a lower end of the metal section being located in the second cryogenic fluid.

12. A fault current limiting system, comprising:
a refrigeration system;
first and second leads; and
a fault current limiting component thermally connected to the refrigeration system so as to be maintained at a cryogenic temperature and having opposing terminals connected to ends of the first and second leads, respectively, the fault current limiting component including a plurality of superconductor particles and a metal in proximity to the superconductor particles, to be driven to a superconducting state by the superconductor particles to provide a superconducting path from the first lead to the second lead.

13. A fault current limiting component made of a superconductor material having an n-value of at least 15 at a temperature of at least 15K.

14. A fault current limiting component, including a plurality of superconductor particles and a metal in proximity to the superconductor particles, to be driven to a superconducting state by the superconductor particles, to provide a superconducting path between opposing terminals thereof.
